(19) United States
(12) Patent Application Publication
(10) Pub. No.: US 2007/0085192 A1
(43) Pub. Date: Apr. 19, 2007

(54) Method for producing micromechanical components in integrated circuits and arrangement of a semiconductor on a substrate

(76) Inventor: Peter Poechmueller, Dresden (DE)

Correspondence Address: SLATER & MATSIL LLP, 17950 PRESTON ROAD, SUITE 1000, DALLAS, TX, 75252, US

(21) Appl. No.: 11/545,820

(22) Filed: Oct. 10, 2006

(30) Foreign Application Priority Data
Oct. 11, 2005 (DE) 102005049111.1-33

(51) Int. Cl. H01L 23/48

(52) U.S. Cl. 257/693

(57) ABSTRACT

A semiconductor component includes a substrate with an active side that includes connection regions disposed thereon. A die includes an upper metallization layer disposed over an upper surface. Integrated circuitry is disposed at the upper surface of the die and a passive side of the die is disposed on the active side of the substrate. The die includes exposed metal patterns at the level of its upper surface side. The exposed metal patterns are deformed in such a way that ends of the exposed metal patterns are connected to the connection regions of the substrate.

This application claims priority to German Patent Application 10 2005 049 111.1-33, which was filed Oct. 11, 2005 and is incorporated herein by reference.

### TECHNICAL FIELD

Embodiments of the invention relate to a method for producing micromechanical components in integrated circuits and also to an arrangement of a semiconductor on a substrate.

### BACKGROUND

In the production of semiconductor memories, one of the greatest problems is to satisfy the increasing requirements for higher speeds while maintaining the same level of costs. Particularly in the near future, massive problems in the production of memories are, therefore, to be expected, since demands for cycle rates greater than 1 GHz will increase.

Particularly the signal transmission between the die and the package is affected by loss. The classic wire bonding suffers from this in particular. In the wire bonding method, a wire is attached both to the contacts of the die and to the contacts of the substrate. For attachment, the wire is liquefied at both ends by coupling in energy. However, due to the great length of the wire and the large contact areas that are necessary, this connecting technique is always accompanied by high parasitics. Furthermore, the wire bridges are technically very complex to produce.

As an alternative, various flip-chip bonding methods can be cited. Flip-chip bonding methods are distinguished by the fact that conductive elevations (bumps) are applied to the die or the substrate. Subsequently, the die is placed with its active side (“face down”) on the substrate and connected to the substrate by adhesive bonding, reflow soldering or other methods. The bumps then form the signal-carrying connections between the die and the substrate. However, not inconsiderable parasitics also occur in the connections between the die and the substrate in the case of this bonding method.

These parasitics are caused by the unfavorable geometrical structure or by the material transitions within the bumps.

Furthermore, by contrast with classic methods, flip-chip bonding is relatively cost-intensive, since, depending on the type of bump, the bumps have to be arranged in additional process steps. According to the prior art, however, flip-chip bonding is the most favorable method if the chip is to be subjected to high cycle rates; the very short connections in the form of bumps are especially conducive to clear signal transmission. However, it must be expected that, in ranges of greater than 1 GHz, problems will also occur here, and the structure of the bumps must be optimized in a complex and cost-intensive manner in order to satisfy the high requirements.

“Tape automated bonding”—referred to hereafter as TAB for short—is an alternative method to flip-chip bonding. Although bumps also have to be applied to the die here, there is no longer any need for further processing steps such as soldering or adhesive bonding.

TAB is distinguished by the fact that terminals are arranged on a film-like material. The die is in this case applied to a rectangular piece of tape. Terminals are arranged on the tape in such a way that they fit exactly on the bonding pads of the die. From there, the terminals are led to the outsides of the rectangle, where they serve for later wiring.

In order to bond the die, it merely has to be applied to the tape in the correct position, which is readily possible with conventional methods of semiconductor production.

The method has the advantage of being very simple and inexpensive to automate and is superior to classic wire bonding in terms of the electrical properties of the bonded connections. However, flip-chip bonding leads to much better connections.

For producing the bumps or similar structures, it is obvious to search for solutions from the area of micromechanical systems (MEMS). In MEMS technology, conventional methods of semiconductor production are used to produce micromechanical arrangements. A known application is, for example, the “Digital Micromirror Device” from Texas Instruments, which is disclosed in U.S. Pat. No. 4,441,791.

However, MEMS technology does not at present offer any known procedures for alternative bonding technologies.

### SUMMARY OF THE INVENTION

In one aspect, the invention provides a method that minimizes the problems of parasitics in the connections between the die and the substrate in a low-cost manner.

In various embodiments, the invention provides a method where at least one metal track is completely exposed selectively in an etching area by an etching process. After the wafer has been singulated to provide a die, the exposed metal track is connected in a mechanical and/or electrically conducting manner outside the remaining die substrate.

The partial exposure of parts of the metal tracks of a chip makes it possible for these exposed parts to be further processed and used for external wiring or purely mechanical purposes. The metal tracks patterned within a chip have the advantage that they are very uniformly defined and go directly into the interior of the chip without any material transitions. Consequently, possible capacitances or inductances are reduced to a possible minimum. Furthermore, it is possible with the method according to the invention to work particularly temperature-sensitive regions gently, since no solder connecting techniques have to be used.

In one particular refinement of the method according to the invention, the exposed metal patterns represent the contacts for external wiring of the die.

This procedure produces an extremely short, high-quality connection into the interior of the chip. In this refinement, bonding pads are unnecessary, which has the accompanying effect of saving space in terms of chip area. Furthermore, the material transition between the bonding pad and the bump or between the bonding pad and the bonding wire no longer occurs, since the exposed metal track itself acts as the “bonding wire.”

In a further embodiment of the invention, it is provided that parts of the metal patterns are completely exposed by targeted undercutting before the chips are singulated in a dicing process on the wafer.

This procedure has the advantage that the wafer remains completely intact up until the dicing process and the metal tracks are only completely exposed by a grinding process.

In a favorable refinement of the method according to the invention, the edges of the chip represent the limits of the etching area.

This is advantageous if metal tracks in the interior of the chip are to be exposed. Exposing the chip area makes it possible to produce ultra-short connections to critical parts of the chip.

In a favorable refinement of the method according to the invention, however, it is also provided that the etching area extends beyond the edges of the chip.

This procedure makes it possible to produce “bonding wires” that are anchored directly in the die and are arranged at the edge of the die in a form similar to the contacts of a finished package. These contacts have all the aforementioned advantages.

Another possible way of setting up the method according to the invention is to arrange the etching area midway between two chips. This allows outer metal tracks on two chips to be simultaneously exposed and chip area is saved.

In a further refinement of the method according to the invention, it is provided that the metal patterns of two adjacent chips on a wafer are patterned in such a way that they interlock with one another at the edges. That is to say, for example, that the ends of the patterned metal tracks of the individual chips engage in one another by the zip fastener principle in a plan view of the wafer. Consequently, in the area of the interlocked metal patterns, the metal patterns of two chips can be exposed at the same time by an etching operation. Furthermore, such an arrangement of the chips on the wafer saves wafer area and consequently costs.

In a favorable refinement of the method according to the invention, it is provided that the exposed metal patterns are mechanically deformed.

Since, depending on the material, the metal patterns are relatively rigid, they must be bent in order to be connected to further elements. It is also conceivable to achieve mechanical effects, such as spring-mounting, securing or the like, by targeted forming.

In a refinement of the invention, it is provided for this purpose that the metal patterns are provided with predetermined breaking points.

Predetermined breaking points may serve here for shortening the metal tracks, or for severing the metal tracks if they are not arranged at the edge of the die.

In a further refinement of the invention, it is provided for this purpose that the predetermined breaking points are mechanically severed.

Alternatively, the invention may also be refined in such a way that the exposed metal patterns are severed by a laser. This dispenses with the need to produce predetermined breaking points in the metal patterns.

In a particularly favorable refinement of the method according to the invention, metal patterns are applied to the surface of the chip and, after the chip has been singulated to give a die, are mechanically deformed in such a way that the metal patterns are bent from the surface of the die downward to the level of the underside of the die.

It is consequently possible to apply the die to a substrate, so that the metal tracks rest on the substrate.

The method may favorably also be refined in such a way that the exposed metal patterns are positively connected to further other patterns.

In particular, in a further refinement it is provided that the exposed metal tracks are connected to further patterns by crimping.

The possibility of purely mechanically bonding a die, or connecting it to other dies, is accompanied by many advantages, since in the case of such a process neither welding nor soldering steps are necessary. Furthermore, mechanical connections in some cases have much better electrical properties than soldered or welded connections.

Another refinement of the method according to the invention provides that the exposed metal patterns are connected to further other patterns with a material bond.

In a refinement of the method according to the invention, at least one of the exposed metal patterns is bonded onto a substrate by means of ultrasonic welding.

In a refinement of the method according to the invention, at least one of the exposed metal patterns is bonded onto a substrate by means of laser welding.

With the two aforementioned embodiments, classic bonding is combined with the method according to the invention. In this case, the exposed metal patterns represent the contacts as an alternative to bumps or bonding wires.

In an alternative embodiment of the method according to the invention, the metal patterns are applied to the surface of the chip. After the chip has been singulated to give a die, the die is applied with its surface to the surface of a substrate.

With this refinement of the method according to the invention, it is possible to shorten the length of the signal-carrying patterns considerably and, as a result, achieve still better electrical properties.

In a refinement of the method according to the invention, the metal patterns are connected to a voltage-carrying power system.

On the arrangement side, embodiments of the invention provide a die having, at the level of its active side, exposed metal patterns, which are deformed in such a way that the ends of the exposed metal patterns at the level of the connecting points are connected to the latter.

In a further refinement of the invention on the arrangement side, the die has at the level of its active side exposed metal patterns that are connected to the connecting points on the active side of the substrate. As a result, the die is mechanically and/or electrically connected to the substrate.

Embodiments of the invention are favorably set up in such a way that the connecting points are mechanically connected to the die. In a way similar to the description of the invention on the method side, this produces a large number of possible ways of arresting or mounting the die within a package.

In a particularly favorable refinement of the invention, the connecting points are conductively configured and establish an electrical connection between the die and the substrate.

### DESCRIPTION OF THE DRAWINGS

The invention is to be explained in more detail below on the basis of an exemplary embodiment. In the associated drawings:

FIG. 1 shows a plan view of a die with variously patterned metal tracks;

FIGS. 2a and 2b, collectively FIG. 2, show plan views of a die detail;

FIGS. 3a, 3b and 3c, collectively FIG. 3, show cross sections of a die during various process steps according to the invention;

FIG. 4 shows a cross section of a die worked according to the invention;

FIG. 5 shows a cross section of a die bonded according to the invention onto a substrate; and

FIG. 6 shows a plan view of a bonded connection established in a way corresponding to FIG. 5.

The following list of reference symbols can be used in conjunction with the figures:
1 die/chip
2 metal patterns
3 etching areas
4 predetermined breaking points
5 wafer
6 substrate
7 connecting point

### DETAILED DESCRIPTION OF ILLUSTRATIVE EMBODIMENTS

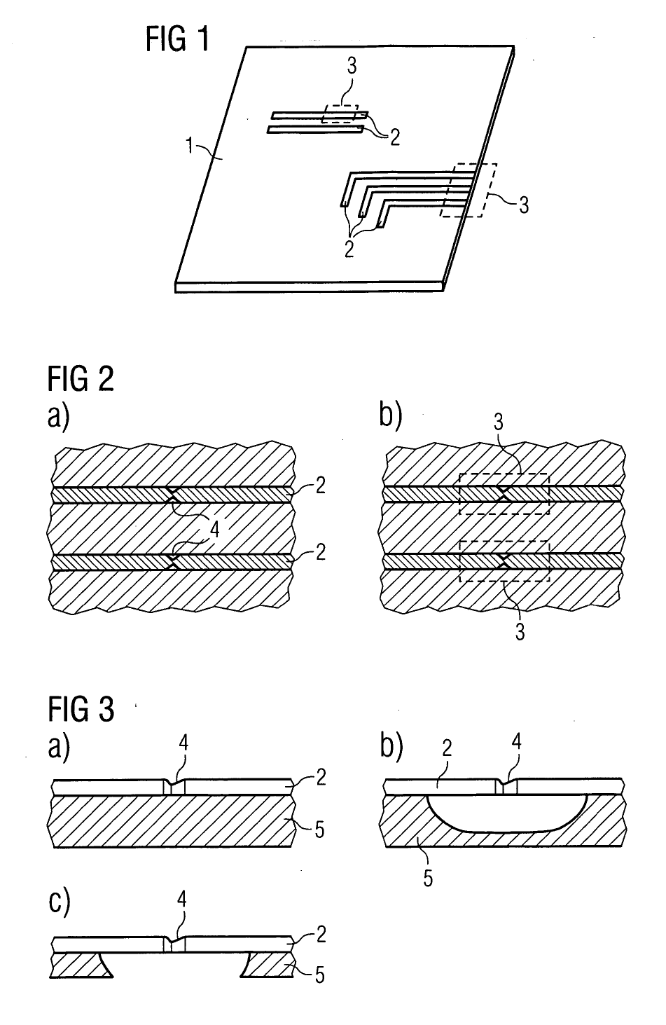

As represented in FIG. 1, various metal patterns 2 are arranged on a die 1 or chip 1. Furthermore, a number of etching areas 3 around the metal patterns 2 are indicated.

Within the etching areas 3, an etching process takes place for the purpose of exposing the depicted metal patterns 2.

In FIG. 2a, two parallel running metal tracks 2 can be seen in the plan view of a die. Both have predetermined breaking points 4 for further working.

In FIG. 2b, the intended etching areas 3 and the line of the section for the further representations (FIGS. 3-5) can also be seen.

FIG. 3 then shows the sequence of the etching process according to the invention, FIG. 3a showing the cross section through the chip 1. A metal track 2 and wafer material 5 underneath it can be seen there. An etching process is then carried out, a cavity being produced under the metal track by targeted undercutting, as represented in FIG. 3b.

After the etching, the grinding down takes place. This involves removing excess wafer material 5. FIG. 3c shows the result of this operation. The exposed metal track 2 with the predetermined breaking point 4 can also be clearly seen.

According to FIG. 4, the metal pattern 2 is then mechanically deformed and thereby separated at the predetermined breaking point 4. One side of the metal track 2 is thereby bent to the level of the passive underside of the chip.

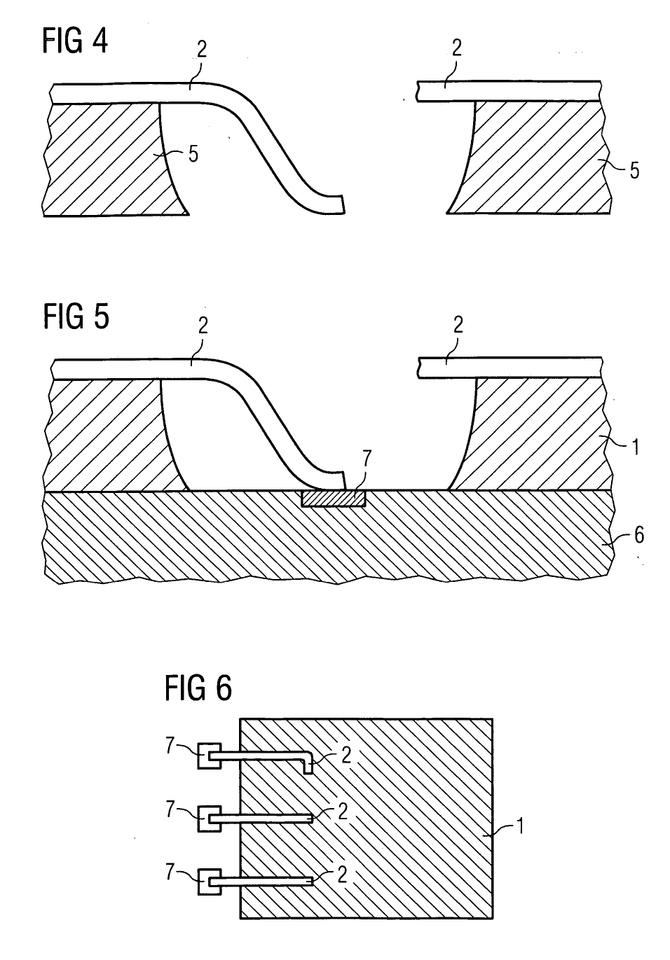

FIGS. 5 and 6 show the final result of the method according to the invention, the singulated die having been applied to a substrate 6 and the deformed metal track 2 resting on a connecting point 7, where it is subsequently welded or soldered.

What is claimed is:

1. A method for producing micromechanical components in integrated circuits, the method comprising:
forming a plurality of integrated circuits at an upper surface of a wafer, the integrated circuits being formed as a plurality of chips;
applying a metallization layer over the upper surface of the wafer, the metallization layer including a plurality of metal tracks each of which includes a lower surface facing the wafer, an upper surface opposed to the lower surface and two side surfaces integrally between the upper surface and the lower surface;
performing an etching process so that after the etching process the upper surface, the lower surface and the two side surfaces of the metal tracks are exposed in an etching area;
singulating the wafer so that each chip is formed into a separate die; and
connecting the exposed metal tracks in a mechanical and/or electrically conducting manner outside the die.

2. The method as claimed in claim 1, connecting the exposed metal tracks in a mechanical and/or electrically conducting manner outside the die comprises connecting the exposed metal tracks in an electrically conducting manner outside the die.

3. The method as claimed in claim 2, wherein connecting the exposed metal tracks in an electrically conducting manner outside the die comprises connecting the exposed metal track to a voltage-carrying power system.

4. The method as claimed in claim 1, wherein performing the etching process comprises performing an undercutting etch from an upper surface of the wafer to a selected depth, the method further comprising grinding back a lower surface of the wafer to a point beyond the selected depth.

5. The method as claimed in claim 1, wherein the etching area in provided in a region between two chips of the plurality of chips.

6. The method as claimed in claim 5, wherein the etching area extends beyond edges of at least one of the two chips.

7. The method as claimed in claim 5, wherein the etching area is arranged midway between the two chips.

8. The method as claimed in claim 5, wherein the metallization layer is patterned such that a single metal trace extends between the two chips such that one of the metal tracks extends in the region between the two chips.

9. The method as claimed in claim 1, further comprising mechanically deforming the exposed metal tracks.

10. The method as claimed in claim 1, further comprising forming a predetermined breaking point within each of the exposed metal tracks.

11. The method as claimed in claim 9, further comprising mechanically severing the predetermined breaking points.

12. The method as claimed in claim 1, further comprising severing the exposed metal patterns using a laser.

13. The method as claimed in claim 1, further comprising, after singulating the wafer, mechanically deforming the exposed metal tracks in such a way that the metal tracks are bent away from the upper surface of the die downward toward an underside of the die.

14. The method as claimed in claim 1, wherein connecting the exposed metal tracks comprises positively connecting the exposed metal tracks to further other patterns.

15. The method as claimed in claim 14, wherein the exposed metal tracks are connected to further other patterns by crimping.

16. The method as claimed in claim 14, wherein the exposed metal tracks are connected to further other patterns with a material bond.

17. The method as claimed in claim 14, wherein at least one of the exposed metal tracks is bonded onto a substrate by means of ultrasonic welding.

18. The method as claimed in claim 14, wherein at least one of the exposed metal tracks is bonded onto a substrate by means of laser welding.

19. The method as claimed in claim 1, further comprising, after singulating the wafer, applying the upper surface of the die to the surface of a substrate.

20. A semiconductor component produced as claimed in claim 1.

21. A semiconductor component comprising:
a substrate including an active side that includes connection regions disposed thereon; and
a die that includes an upper metallization layer disposed over an upper surface, integrated circuitry being disposed at the upper surface of the die, wherein a passive side is disposed on the active side of the substrate,
wherein the die includes exposed metal patterns at the level of its upper surface side, the exposed metal patterns being deformed in such a way that ends of the exposed metal patterns are connected to the connection regions of the substrate.

22. The semiconductor component as claimed in claim 21, wherein the connection regions are mechanically connected to the die.

23. The semiconductor component as claimed in claim 21, wherein the exposed metal patterns establish an electrical connection between the die and the substrate.
